(19) United States
(12) Patent Application Publication
(10) Pub. No.: US 2026/0323894 A1
(43) Pub. Date: Oct. 15, 2026

(54) A DISPLAY AND A THERMAL MANAGEMENT SYSTEM

(71) Applicant: Kuori Oy, Espoo (FI)

(72) Inventors: Jarkko Jokelainen, Espoo (FI); Xavier Veillet, Helsinki (FI)

(73) Assignee: Kuori Oy, Espoo (FI)

(21) Appl. No.: 19/482,079

(22) PCT Filed: Apr. 11, 2024
(86) PCT No.: PCT/FI2024/050168

§ 371 Date: Nov. 6, 2025

(30) Foreign Application Priority Data
May 12, 2023 (FI) 20235538

(51) Int. Cl. H05K 7/20; G02F 1/1333; G02F 1/1335

(52) U.S. Cl. CPC H05K 7/20972; G02F 1/133385; G02F 1/133628; H05K 7/20145; H05K 7/2039

(57) ABSTRACT

A display including housing having frame and first window attached to the frame; first display element arranged in housing facing first window, parallel to first window and separated from first window by first air gap; cooling air channels for flow of cooling air (214, 614) through cooling air channels, wherein cooling air channels are arranged partially inside of the housing; first air circulation system arranged to circulate first air enclosed in first display element; and second air circulation system arranged to circulate second air between first air gap and heat exchanger channels wherein cooling air channels, first air circulation system and second air circulation system are airtight in respect to each other; first air circulation system is thermally connected to cooling air channels; and second air circulation system is thermally connected, via heat exchanger channels, to cooling air channels.

### TECHNICAL FIELD

The present disclosure relates to displays.

### BACKGROUND

Outdoor display screens have become increasingly popular in recent years due to their ability to attract attention and engage audiences. One of the most common uses of outdoor display screens is for advertising purposes. The outdoor display screens can be used to display dynamic and eye-catching content, such as videos, animations, and images, that can quickly grab the attention of people passing thereby. As a result, businesses and organizations can use the outdoor display screens to promote their products, services, or events to a large audience in a highly effective and engaging way. Typically, the outdoor display screens are located in high-traffic areas, such as shopping malls, airports, and busy city centres. Moreover, the outdoor display screens can also be used to provide information to the public, such as weather updates, news headlines, or event schedules. They can also be used for entertainment purposes, such as displaying live sports events or concerts.

However, conventional outdoor display screens are vulnerable to weather conditions. The outdoor display screens are often exposed to harsh weather conditions such as rain, wind, snow, and extreme temperatures, which can damage or destroy the screens and other electronic components. This can result in costly repairs or replacements, and downtime. Typically, lcd panels arranged in the outdoor display screen used in outdoor environments are extremely susceptible to high temperatures, especially the display screens those are arranged in the direct sunlight. The lcd panels of the conventional outdoor display screens are usually unable to handle temperature above 65 °C. The temperature above the 65 °C may cause permanent damage to the lcd panels. Typically, the lcd panels undergo pixel-burning or darkening. Large panels are difficult and expensive to replace.

Current solutions involve the use of outside air (such as natural air) to cool the lcd panels, however, the use of outside air requires filters to avoid the ingress of dust and dirt. However, the filters have the disadvantage as they require frequently replacement. Moreover, to avoid the ingress of dust and dirt and use of filters, the compressors are used to provide the clean air. However, the use of compressor increases the cost of operation of the outdoor display screens and requires regular maintenance. In some cases, the use of more resilient lcd panels is used that can withstand temperatures above 100 °C. However, panels of this quality are not universally and frequently available.

Therefore, in light of the foregoing discussion, there exists a need to overcome the aforementioned drawbacks.

### SUMMARY

The aim of the present disclosure is to provide a device to effectively dissipate heat therein. The aim of the present disclosure is achieved by a display, as defined in the appended independent claims to which reference is made to. Advantageous features are set out in the appended dependent claims.

In a first aspect, an embodiment of the present disclosure provides a display, according to claim 1.

Throughout the description and claims of this specification, the words “comprise”, “include”, “have”, and “contain” and variations of the words, for example “comprising” and “comprises”, mean “including but not limited to”, and do not exclude other components, integers or steps. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 is a schematic illustration of cross-sectional view of a display, in accordance with an embodiment of the present disclosure;

FIG. 2 is a schematic illustration of perspective view of a display 100 without a first window depicting flow of air, in accordance with an embodiment of the present disclosure;

FIG. 3 is a schematic illustration of top cross-sectional view of a display, in accordance with an embodiment of the present disclosure;

FIG. 4 is a schematic illustration of top cross-sectional view of a display, in accordance with an embodiment of the present disclosure;

FIG. 5 is a schematic illustration of a side by side arrangement of cooling air channels and heat exchanger channels in an alternate manner, in accordance with an embodiment of the present disclosure; and

FIG. 6 is a schematic illustration of a display implemented as a double sided display, in accordance with an embodiment of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In a first aspect, the present disclosure provides a display comprising:
a housing having a frame and a first window attached to the frame;
a first display element arranged in the housing facing the first window, parallel to the first window and separated from the first window by a first air gap;
cooling air channels for a flow of a cooling air through the cooling air channels, wherein the cooling air channels are arranged partially inside of the housing;
a first air circulation system arranged to circulate first air enclosed in the first display element; and
a second air circulation system arranged to circulate second air between the first air gap and heat exchanger channels, wherein
   the cooling air channels, the first air circulation system and the second air circulation system are airtight in respect to each others;
   the first air circulation system is thermally connected to the cooling air channels; and
   the second air circulation system is thermally connected, via the heat exchanger channels, to the cooling air channels.

The present disclosure provides the aforementioned display for effective dissipation of heat from the aforementioned display. The display is designed to enable the first air circulation system and the second circulation system in the display which rapidly remove the heat from the display before temperatures inside the display reaches a high temperature. As a result, the display is beneficially prevented from any damage due overheating. Advantageously, the display is suitable to be installed in environments involving extreme weather conditions (for example, high temperatures, heavy rainfall, snowfall, and the like). Moreover, the display is not dependent on the ingress of outside air for its cooling and require minimum maintenance.

Throughout the present disclosure, the term “display” refers to a display screen that displays visual information from wired or wireless sources.

Optionally, the display may include but is not limited to television, monitors, computer monitors, laptop computers, personal computers. Optionally, the display may be selected from liquid crystal display (LCD) light-emitting diode (LED), backlit LCD, thin-film transistor (TFT) LCD, organic LED (OLED), Quantum dot (QLED) display, OLED display, AMOLED display, Super AMOLED display. Optionally, the display is used as one of: an advertisement billboard, an electronic scoreboard, an announcement board on railway stations or airports, and the like.

The display comprises the housing having the frame and the first window attached to the frame. Throughout the present disclosure, the term “housing” refers to a casing or shell that act as a protective covering arranged on an outer boundary of the display. Notably, the housing acts as a weatherproof casing that protects the display from extreme weather conditions such as rain or snowfall. It will be appreciated that the frame, which is a non-transparent part of the housing is arranged around a periphery of the display. Optionally, the frame is made of a metallic or a non-metallic material based on a purpose for which the display is to be used. Throughout the present disclosure, the term “first window” refers to a transparent part of the housing that is arranged in front of the display which allows to view contents that are displayed over the display through the first window. Optionally, the first window is made up of glass.

Moreover, the display comprises the first display element arranged in the housing facing the first window, parallel to the first window and separated from the first window by a first air gap. Throughout the present disclosure, the term “first display element” refers to basic elements of the display which are required for rendering the information to be displayed on the display in form of pixels. Optionally, the first display element includes LCD cells. Notably, arranging the first display element parallel to and facing the first window makes the information that is displayed on the first display element visible to an external world, as the first window is transparent. It will be appreciated that heat is generated by the first display element while displaying the information. The first display element also absorbs heat from an external atmosphere (for example, from sunlight falling over the display). Throughout the present disclosure, the term “first air gap” refers to a hollow space that is present between the first window and the first display element. Notably, the presence of the first air gap enables circulation of air between the first window and the first display element. Notably, a part of the heat that is generated inside the display is enclosed within the first display element, while the remaining part of the heat inside the display is present in the first air gap between the first window and the first display element.

Optionally, the first display element is arranged as a stack of: a first light modulator, a first light diffuser and a first backlight, wherein the first light diffuser is arranged between the first light modulator and the first backlight, the first light modulator and the first light diffuser have second air gap between them, the first light diffuser and the first backlight have a third gap between them, and wherein the first display element is surrounded in a casing to enclose the first air in the casing. Throughout the present disclosure, the term “first light modulator” refers to an optical device that modulates intensity or phase of the light to create desired images on the display. Throughout the present disclosure, the term “first light diffuser” refers to an optical element that scatter light rays in different directions and creates a uniform and even distribution of light. Throughout the present disclosure, the term “first backlight” refers to component that provides a required illumination for displaying the images on the display. The technical effect of arranging the first display element as the stack of: the first light modulator, the first light diffusor and the first backlight is that the stack enables to render images on the display with clarity and accuracy on the display. Notably, the stack is arranged in the display such that a side of the stack where the first light modulator is located is placed near the first window, while another side of the stack where the first backlight is located is placed near the cooling air channels.

Herein, the term “second air gap” refers to the hollow space that is present between the first light modulator and the first light diffuser. Likewise, the term “third air gap” refers to the hollow space that is present between the first light diffuser and the first backlight. Advantageously, the presence of the second air gap and the third air gap provides a passage for circulation of the first air that is enclosed in the first display element. Furthermore, according to an embodiment the first backlight is in thermal connection with the cooling air channels. Those are for example in a physical contact with the cooling air channels.

Furthermore, the device comprises the cooling air channels for the flow of the cooling air through the cooling air channels, wherein the cooling air channels are arranged partially inside of the housing. Throughout the present disclosure, the term “cooling air channels” refers to air channels that act as a passage for the cooling air to pass and thus, enable an exchange of heat in the display. Herein, the cooling air channels may have fins on their interior or exterior surface that allows the cooling air channels to provide a more efficient exchange of heat with the cooling air. It will be appreciated that each cooling air channel is made up of thin walls which increases a number of the cooling air channels, increases a surface area of the cooling air channels present in the display, and decreases a friction in the cooling air flowing through the cooling air channels. Notably, the cooling air channels enable the exchange of heat by absorbing the heat that is present in the device. Subsequently, the exchange of heat with the cooling air in the cooling air channels results in the removal of heat from the display. It will be appreciated that the cooling air channels are made up of a thermally conductive material which facilitates the exchange of heat in the cooling air channels. Optionally, the cooling air channels are integrated on a backlight plate of the first display element making cooling more effective and optimizing the use of material. Optionally, the backlight plate can have vertical perforations to allow air from within the LCD enclosure to mix with the internal air circulations to enhance cooling.

Optionally, cooling air channels are arranged between a first edge and a second edge of the frame and through the housing, wherein the first edge and the second edge are opposite edges of the frame, and the cooling air is input to the cooling air channels from first openings of the cooling air channels arranged through the first edge and is output from second openings of the cooling air channels through the second edge. In this regard the cooling channels are arranged in the display throughout the complete length of the housing between two opposite edges of the housing which is the first edge and the second edge. Notably, the first edge and the second edge of the housing are both located around two opposite edges of the periphery of the display. The technical effect of having the first openings and the second openings arranged on the first edge and the second edge respectively, is that cool air from the external atmosphere can enter the display through the first openings and the heat can be removed from the display via the cooling air channels through the second openings. In addition, there is no need to use additional air filters in the display when the first openings are located on top of the display allowing clean cool air to enter the display making cooling more effective and the display maintenance easier.

Furthermore, the device comprises the first air circulation system arranged to circulate the first air enclosed in the first display element. Throughout the present disclosure, the term “first air circulation system” refers to a system that enables the circulation of the first air within the first display. Herein the first air contains the heat that is generated in displaying the information over the first display element. It will be appreciated that the circulation of the first air in the first circulation system facilitates the movement of the heat that is generated in the first display element towards the cooling air channels for the exchange of heat to take place between the first air and the cooling air channels. In addition, it facilitates movement of heat to be enhanced from the first air circulation system to a second air circulation system. Benefit of this is that efficient cooling can be arranged for the heat dissipated by the back light. Part of the heat is exchanged due to circulation of (back light heated) air from the third air gap to the second air gap. The second air gap is in thermal connection with the second air circulation system thus enabling cooling of the air of the first air circulation system.

Optionally, the first air circulation system is arranged to circulate the first air enclosed in the first display element, by circulating it between the second air gap and the third air gap. In this regard, the hollow space that is present in the second air gap and the third air gap is used for the circulation of the first air enclosed in the first display element. The technical effect of circulating the first air between the second air gap and the third air gap is that since the third air gap is located near the cooling air channels, thus, beneficially, the exchange of heat takes place easily when the first air is present in the third air gap.

Furthermore, the device comprises the second air circulation system arranged to circulate the second air between the first air gap and the heat exchanger channels. Throughout the present disclosure, the term “second air circulation system” refers to another system apart from the first circulation system that enables the circulation of the second air. Herein, the second air contains the part of the heat generated in the first display element that is present in the first air gap. Throughout the present disclosure, the term “heat exchanger channels” refers to those channels that are configured to receive the second air from the first air gap in order to provide a medium for heat exchange to take place between the second air and cooling air channels. It will be appreciated that each heat exchanger channel is made up of thin walls which increases a number of the heat exchanger channels, increases a surface area of the cooling air channels present in the display, and decreases a friction in the second air flowing through the heat exchanger channels. Notably, the second air circulation system enables the movement of the part of the heat that escapes the first display element from the first air gap to the heat exchanger channels. Subsequently, the part of the heat is removed from the display by the heat exchange between the heat exchanger channels and the cooling air channels. It will be appreciated that the heat exchanger channels are lined with a thermally insulative material to prevent the heat in the second air from intermixing with the heat in the first air which can significantly increase a temperature inside the display and cause damage to the display. Optionally, the cooling air channels are integrated on a backlight plate of the first display element making cooling more effective and optimizing the use of material.

Optionally, active cooling elements are arranged in the heat exchanger channels. Throughout the present disclosure, the term “active cooling elements” refers to elements which are to provide a cooling effect by enabling a transfer of heat. The technical effect of arranging the active cooling elements in the heat exchanger channels, beneficially, increases the transfer of heat that is exchanged in the heat exchanger channels and effectively reduces the temperature inside the display. Optionally, the active cooling elements are peltier elements (i.e., thermoelectric coolers). The peltier elements are placed at the second edge i.e., at the bottom of the heat exchanger channels, such that the hot first air that flows in front of the first display element is cooled by the peltier elements, and the excess heat generated by the peltier elements is expelled by the cooling air. This further cools the first display element without generating additional heat elsewhere in the housing of the display.

Optionally, the cooling air channels and the heat exchanger air channels are arranged side by side in an alternating manner in respect to each other, in thermal connection with each other and forming a mat of air channels, wherein the mat is parallel to the first display element. In this regard, each of the cooling air channels is arranged between two of the heat exchanger channels. Likewise, each of the heat exchanger elements is arranged between two of the cooling air channels. Herein the mat of the air channels refers to the side-by-side arrangement of the cooling air channels and the heat exchanger channels in the alternating manner spread throughout a complete length and breadth of the display. The technical effect of arranging the cooling air channels and the heat exchanger channels side by side in the alternating manner is that the exchange of the heat with the cooling air channels take place using both the first air circulation system and the second air circulation system simultaneously, to increase an amount of the heat that is removed from the display.

Optionally, the first air circulation system is arranged to circulate the first air around the first light diffuser in a first direction and the second air circulation system is arranged to circulate the second air around the first display element in a second direction, where the second direction is perpendicular to the first direction. Throughout the present disclosure, the term “first direction” refers to a direction in which the first air is made to circulate around the first light diffuser. Notably the first direction is parallel to an axis at which the first light diffuser is arranged. Throughout the present disclosure, the term “second direction” refers to a direction in which the second air is made to circulate around the first display element. Notably, the second direction is parallel to an axis at which the first display element is arranged. It will be appreciated that the second direction being perpendicular to the first direction implies that the first air flows in an interlaced manner with respect to the second air. Optionally, the second direction can be parallel to the first direction. The technical effect of circulating the first air in the first direction and the second air in the second direction is that it makes it possible to transfer simultaneously hot air from both sides of the first display element wherein the first air and the second air are not mixing with each other and thus the cooling is more effective. Optionally the first direction and the second direction are interchangeable.

Optionally, the cooling air channels of the mat of air channels have a first flat outer surface arranged to be in contact with an outer surface of a backlight of the first display element and the heat exchange channels have a first insulating arrangement to thermally insulate the heat exchanger channels from the outer surface of the backlight. The technical effect of the first flat outer surface of the cooling air channels arranged to be in contact with the outer surface of the backlight is that the heat from the second air that is present in the third air gap above the backlight is easily transferred to the cooling air channels as the first flat outer surface is arranged to be in contact with the outer surface of the backlight. The technical effect of the first insulating arrangement to thermally insulate the heat exchanger channels from the outer surface of the backlight is that the heat from the heat exchanger channels is prevented from being transferred to the third air gap to cumulate with the heat present in the second air, and beneficially, the display is prevented from being damaged due to increased overall heat in the display. Optionally insulating arrangement can be done by leaving a space between the heat exchanger channels and the outer surface of the backlight wherein the shape of the space can be a square, a triangle, a half of a circle, or a half of an oval. Optionally insulating arrangement can be done by using rectangular aluminium extrusion only with cooling air channels, wherein heat exchanger channels are between cooling air channels, and heat exchanger channels are formed by sides of the aluminium extrusion used to form cooling air channels.

Furthermore, the cooling air channels, the first air circulation system and the second air circulation system are airtight in respect to each other. In this regard, each of the cooling air channels, the first air circulation system and the second air circulation system, all work operate independently but are integrated in the same display. Subsequently, the airtight arrangement between the cooling air channels, the first air circulation system and the second air circulation system in respect to each other enables to prevent any mixing or contamination of air between the cooling air channels, the first air circulation system and the second air circulation system, further prevents any exchange of heat there between, and further makes it possible to avoid use of filters at the entrance of the outside air. Optionally, the cooling air channels, the first air circulation system and the second air circulation system are designed to have sealed connections and be physically separated from each other in order to ensure that the cooling air channels, the first air circulation system and the second air circulation system are airtight in respect to each other.

Term airtight refers to a setup in which air and dust is not exchanged between the circulation systems to an extend it is harmful for operation of the display. Cooling air channels are subject to outdoor (of the display) air thus are likely to have dust and contaminations. The second air circulation system is arranged to be (hermitically/airtightly) sealed from the cooling air. However, small openings/cracks might appear over time between the cooling air channel and second air circulation system. These can arise due vibrations of the display, aging, hits, manufacturing defects, vandalism etc. For this reason, small amounts of dust and other impurities might accumulate to the second air circulation system over time. Since, the first air circulation system is further airtight in respect to the second air circulation system, possible impurities (from said cracks) in the second air circulation system are not critical for the functionality of the first display element. This hierarchical structure of air circulation systems enables to keep the first display element internal structures clean. Furthermore, the first air circulation system is thermally connected to the cooling air channels. In this regard, the thermal connection between the first air circulation system and the cooling air channels enables effective transfer of the heat between the first air circulation system and the cooling air channels. Thus, the heat present in the first air is transferred from the first air circulation system to the cooling air channels from where the heat is removed from the display.

Furthermore, the second air circulation system is thermally connected, via the heat exchanger channels, to the cooling air channels. In this regard, the thermal connection between the second air circulation system and the cooling air channels via the heat exchanger channels enables the effective transfer of the heat between the second air circulation system and the cooling air channels. Thus, the heat present in the second air first flows from the first air gap to the heat exchanger channels and subsequently, the heat is transferred from the heat exchanger channels to the cooling air channels from where the heat is removed from the display.

Optionally, the display further comprises a second window on an opposite side of the first window and a second display element arranged in the housing facing the second window, parallel to the second window and separated from the second window by a fourth air gap. Herein, the second window refers to another window present in the display that is identical in its design, configuration and operation to the first window. Likewise, the second display element is another display element present in the display that is identical in its design, configuration and operation to the first display element. Herein, the fourth air gap refers to the hollow space that is present between the second window and the second display element. In this regard, the display is comprising the first window and the second window on two opposite faces of the display respectively, where the first display element is arranged facing the first window and the second display element is arranged facing the second window. Subsequently, the displayed information is visible from two opposite faces of the display. The technical effect of the display comprising the second window on the opposite side of the first window and the second display element arranged in the housing facing the second window is that, beneficially, the display acts as a double-sided display.

Optionally, the second display element comprises a third air circulation system arranged to circulate third air enclosed in the second display element, and a fourth air circulation system arranged to circulate fourth air between the fourth air gap and the heat exchanger channels. Throughout the present disclosure, the term “third air circulation system” refers to the air circulation system that enables the circulation of the third air within the second display element. Notably, the heat that is generated in the second display element is present in the third air. Throughout the present disclosure, the term “fourth air circulation system” refers to the air circulation system that enables the circulation of the fourth air between the fourth air gap and the heat exchanger channels. The technical effect of the second display element comprising the third air circulation system and the fourth circulation system is that the heat that is generated in the second display element is removed from the display in an identical way by which the heat that is generated by the first display element is removed from the display.

Optionally, each air circulation system circulates its corresponding air using individually controllable fans, each individually controllable fan being dedicated to a different air circulation system. Throughout the present disclosure, the term “controllable fans” refers to fans which can be controlled to operate at different speeds to facilitate the circulation of the air in the corresponding air circulation systems in which the respective controllable fans are installed. Notably, each of the controllable fan is individually controlled without any dependence on the remaining of the controllable fans present in the display. Optionally, the individually controlled fans are controlled via pulse width modulation or a change in voltage supplied to the individually controllable fans. The technical effect of the each of the individually controllable fan being dedicated to the different air circulation system is that the corresponding air circulating in a given air circulation system can be kept separate from the other different air circulation systems. Advantageously, individually, controlling the controllable fans allows the display to use only that much power that is required and helps in power saving.

Optionally, the display is capable of being arranged in an outdoor environment. In this regard, when the display is arranged in the outdoor environment, any heat that is generated in the display due to any sunlight entering the display is effectively dissipated from the display using the first air circulation system and the second circulation system. The technical effect of the display capable of being arranged in the outdoor environment is that the display is able to withstand extreme weather conditions (such as high temperatures in the outdoor environment) without getting damaged.

In an embodiment, when the display is arranged in the outdoor environment where the temperature is below a threshold temperature, the heat generated in display is significantly less. Subsequently, only the individually controllable fans arranged in the second air circulation system is operational, and thus, the heat from the display is removed using only the second air circulation system. Thus, advantageously, the power required by the display significantly reduces.

### DETAILED DESCRIPTION OF THE DRAWINGS

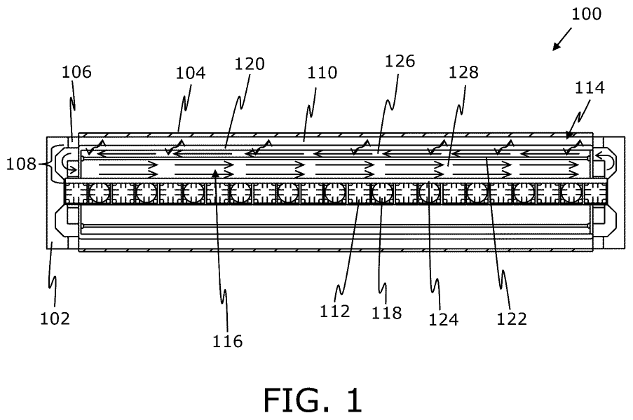

Referring to FIG. 1, there is shown a schematic illustration of cross-sectional view of a display 100, in accordance with an embodiment of the present disclosure. As shown in FIG. 1, a display 100 comprises a housing 102 having a frame 106 and a first window 104 attached to the frame 106. The display 100 includes a first display element 108 arranged in the housing 102 facing the first window 104, parallel to the first window 104 and separated from the first window 104 by a first air gap 110. The display 100 also comprises a cooling air channels 112 for a flow of a cooling air through the cooling air channels 112, wherein the cooling air channels 112 are arranged partially inside of the housing 102. The display 100 comprises a first air circulation system 116 arranged to circulate first air enclosed in the first display element 110 and a second air circulation system 114 arranged to circulate second air between the first air gap 110 and heat exchanger channels 118. Moreover, the cooling air channels 112, the first air circulation system 116 and the second air circulation system 114 are airtight in respect to each other. Furthermore, the first air circulation system 116 is thermally connected to the cooling air channels 112 and the second air circulation system 114 is thermally connected, via the heat exchanger channels 118, to the cooling air channels 112.

Optionally, the first display element 108 is arranged as a stack of: a first light modulator 120, a first light diffuser 122 and a first backlight 124, wherein the first light diffuser 122 is arranged between the first light modulator 120 and the first backlight 124, the first light modulator 120 and the first light diffuser 122 have second air gap 126 between them, the first light diffuser 122 and the first backlight 124 have a third gap 128 between them.

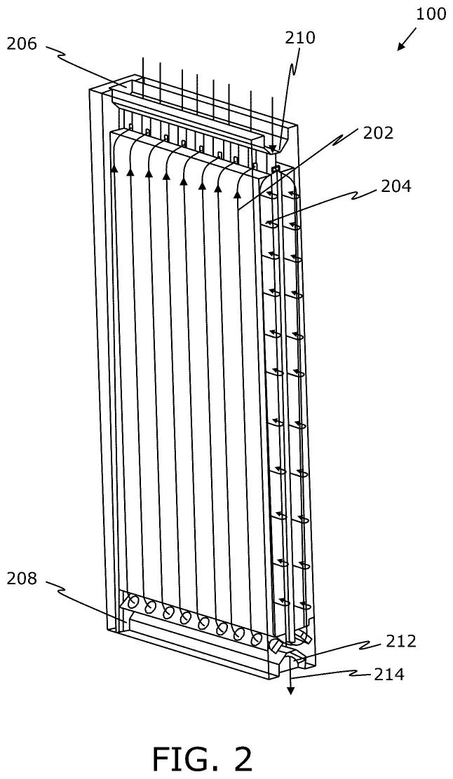

Referring to FIG. 2, there is shown a schematic illustration of a perspective view of a display 100 without a first window depicting flow of air, in accordance with an embodiment of the present disclosure. The display 100 comprises a cooling air channels for a flow of a cooling air through the cooling air channels. As shown, a first air circulation system 116 arranged to circulate first air 204 enclosed in the first display element 108 and a second air circulation system 114 arranged to circulate second air 202. The first air 204 circulates enclosed in the first display element 108. The second air 202 circulates between a first air gap 110 and heat exchanger channels 118.

The cooling air channels are arranged between a first edge 206 and a second edge 208 of a frame 106 and through the housing, wherein the first edge 206 and the second edge 208 are opposite edges of the frame 106, and the cooling air is input to the cooling air channels from first opening 210 of the cooling air channels arranged through the first edge 206 and is output from second opening 212 of the cooling air channels through the second edge 208. The first air circulation system 114 is arranged to circulate the first air 204 around the first light diffuser 122 in a first direction and the second air circulation system 116 is arranged to circulate the second air 202 around the first display element 108 in a second direction, which the second direction is perpendicular to the first direction. Moreover, a cooling air 214 flows through the cooling air channels 112.

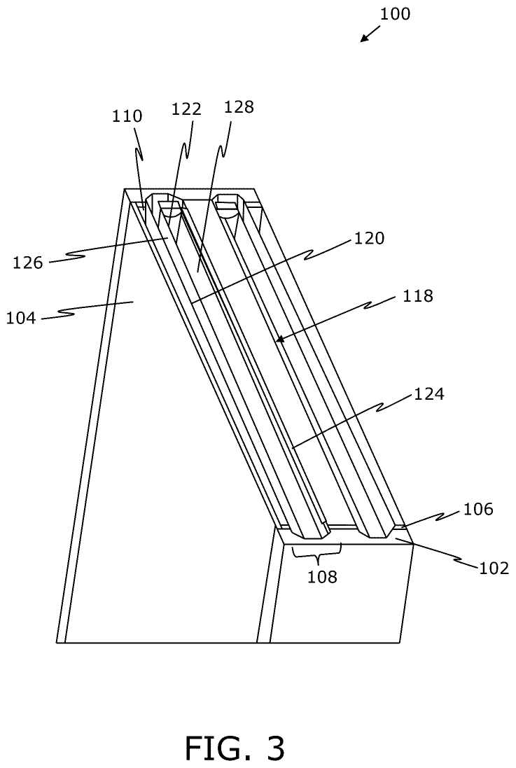

Referring to FIG. 3, there is shown a schematic illustration of top cross-sectional view of a display 100, in accordance with an embodiment of the present disclosure. The display 100 comprises a housing 102 having a frame 106 and a first window 104 attached to the frame 106. The display 100 includes a first display element 108 arranged in the housing 102 facing the first window 104, parallel to the first window 104 and separated from the first window 104 by a first air gap 110. Optionally, the first display element 108 is arranged as a stack of: a first light modulator 120, a first light diffuser 122 and a first backlight 124, wherein the first light diffuser 122 is arranged between the first light modulator 120 and the first backlight 124, the first light modulator 120 and the first light diffuser 122 have second air gap 126 between them, the first light diffuser 122 and the first backlight 124 have a third gap 128 between them.

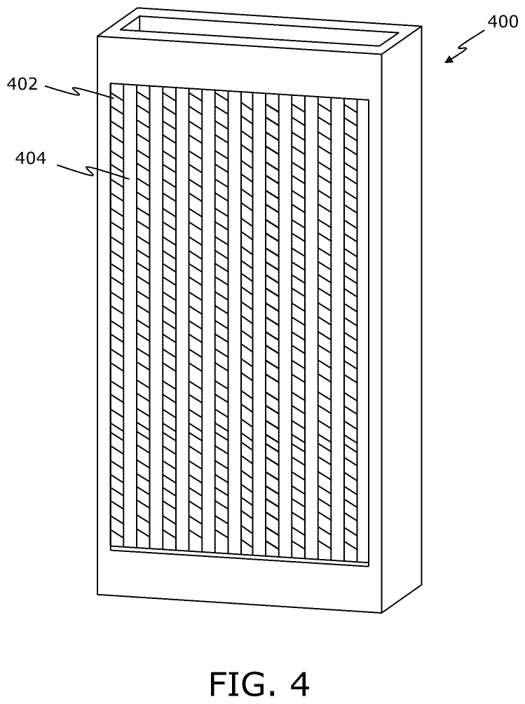

Referring to FIG. 4, there is shown a schematic illustration of a perspective view of a mat of air channels 400, in accordance with an embodiment of the present disclosure. As shown in FIG. 4, the mat of air channels is having alternate layers of cooling air channels 402 and heat exchanger channels 404, wherein the heat exchanger channels 404 are made of thermally insulative material to isolate the first air and the second air from each other.

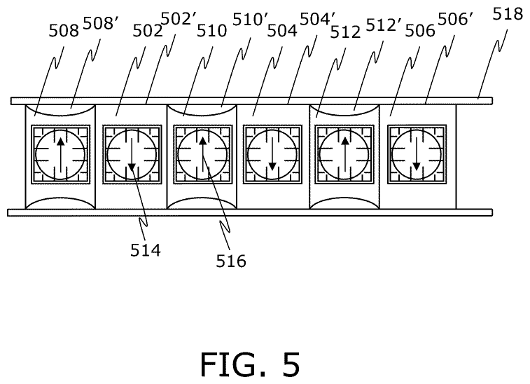

Referring to FIG. 5, there is shown a schematic illustration of a side by side arrangement of cooling air channels and heat exchanger channels in an alternate manner, in accordance with an embodiment of the present disclosure. As shown in FIG. 5, each of the cooling air channels (depicted as a first cooling air channel 502, a second cooling air channel 504 and a third cooling air channel 506) are arranged sequential to one of the heat exchanger channels (depicted as a first heat exchanger channel 508, a second heat exchanger channel 510 and a third heat exchanger channel 512). Likewise, each of the heat exchanger channels 508, 510 and 512 are arranged sequential to one of the cooling air channels 502, 504 and 506. For example, the first heat exchanger channel 508 is arranged sequential to the first cooling air channel 502, and the second cooling air channel 504 is arranged sequential to the first heat exchanger channel 508. Herein, a cooling air 514 flows from a top to bottom direction in the cooling air channels 502, 504, and 506, wherein the cooling air channels 502, 504 and 506 have a first flat outer surface 502′, 504′ and 506′ arranged to be in contact with an outer surface of a backlight 518, and a second air 516 flows from a bottom to top direction in the heat exchanger channels 508, 510 and 512, wherein the heat exchanger channels 508, 510 and 512 have a first insulating arrangement 508′, 510′ and 512′ to thermally insulate the heat exchange channels 508, 510 and 512 from the outer surface of the backlight 518. In the FIG. 5 example the insulating arrangement is a cavity with air.

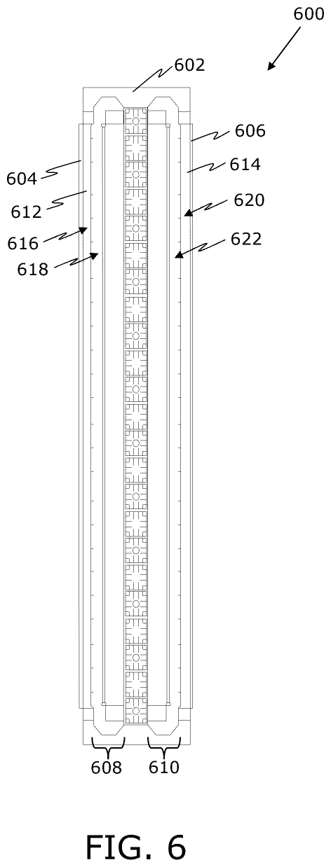

Referring to FIG. 6, there is shown a schematic illustration of a display 600 implemented as a double sided display, in accordance with an embodiment of the present disclosure. As shown in FIG. 6, the display 600 comprises a housing 602. The display 600 comprises a first window 604 and a second window 606 on an opposite side of the first window 604. Moreover, the device 600 comprises a first display element 608 arranged in the housing 602 parallel to the first window 604 and a second display element 610 arranged in the housing 602 parallel to the second window 606. The first window 604 is separated from the first display element 608 by a first air gap 612 and the second window 606 is separated from the second display element 610 by a fourth air gap 614. The first display element 608 comprises a first air circulation system 618 and a second air circulation system 616. Moreover, the second display element 614 comprises a third air circulation system 622 and a fourth air circulation system 620.

1. A display comprising:
a housing having a frame and a first window attached to the frame;
a first display element arranged in the housing facing the first window, parallel to the first window and separated from the first window by a first air gap;
cooling air channels for a flow of a cooling air through the cooling air channels, wherein the cooling air channels are arranged partially inside of the housing;
a first air circulation system arranged to circulate first air enclosed in the first display element; and
a second air circulation system arranged to circulate second air between the first air gap and heat exchanger channels,
wherein
the cooling air channels, the first air circulation system and the second air circulation system are airtight in respect to each other;
the first air circulation system is thermally connected to the cooling air channels; and
the second air circulation system is thermally connected, via the heat exchanger channels, to the cooling air channels,
wherein the cooling air channels and the heat exchanger channels are arranged side by side in an alternating manner in respect to each other, in thermal connection with each other and forming a mat of air channels, wherein the mat is parallel to the first display element,
wherein, the cooling air channels of the mat of air channels have a first flat outer surface arranged to be in contact with an outer surface of a backlight of the first display element, and wherein the heat exchanger channels have a first insulating arrangement to thermally insulate the heat exchange channels from the outer surface of the backlight.

2. The display according to claim 1, wherein the first display element is arranged as a stack of: a first light modulator, a first light diffuser and a first backlight, wherein the first light diffuser is arranged between the first light modulator and the first backlight, the first light modulator and the first light diffuser have second air gap between them, the first light diffuser and the first backlight have a third gap between them, and wherein the first display element is surrounded in a casing to enclose the first air in the casing.

3. The display according to claim 1, wherein the cooling air channels are arranged between a first edge and a second edge of the frame and through the housing wherein the first edge and the second edge are opposite edges of the frame, and the cooling air is input to the cooling air channels from first opening of the cooling air channels arranged through the first edge and is output from second opening of the cooling air channels through the second edge.

4. The display according to claim 2, wherein the first air circulation system is arranged to circulate the first air enclosed in the first display element, by circulating it between the second air gap and the third air gap.

5. (canceled)

6. The display according to claim 2, wherein the first air circulation system is arranged to circulate the first air around the first light diffuser in a first direction and the second air circulation system is arranged to circulate the second air around the first display element in a second direction, where the second direction is perpendicular to the first direction.

7. (canceled)

8. The display according to claim 1, wherein the display further comprises a second window on an opposite side of the first window and a second display element arranged in the housing facing the second window, parallel to the second window and separated from the second window by a fourth air gap.

9. The display according to claim 8, wherein the second display element comprises a third air circulation system arranged to circulate third air enclosed in the second display element, and a fourth air circulation system arranged to circulate fourth air between the fourth air gap and the heat exchanger channels.

10. The display according to claim 1, wherein each air circulation system circulates its corresponding air using individually controllable fans, each individually controllable fan being dedicated to a different air circulation system.

11. The display according to claim 1, wherein active cooling elements are arranged in the heat exchanger channels.

12. The display according to claim 1, wherein the display is capable of being arranged in an outdoor environment.
